(19) United States
(12) Patent Application Publication
(10) Pub. No.: US 2020/0083856 A1
(43) Pub. Date: Mar. 12, 2020

(54) AUDIO CONTROL SYSTEM

(71) Applicant: PANASONIC INTELLECTUAL PROPERTY MANAGEMENT CO. LTD., Osaka (JP)

(72) Inventors: Phyo TIN THAN, Singapore (SG); Nino NOEL DOOC, Singapore (SG); Roy LIM ENG CHYE, Singapore (SG); Chandra SUWANDI WIJAYA, Singapore (SG)

(21) Appl. No.: 16/125,291

(22) Filed: Sep. 7, 2018

(51) Int. Cl. H03G 3/32; H04R 29/00; G10L 25/78; G10L 15/25; G10K 11/178

(52) U.S. Cl. CPC H03G 3/32; H04R 29/002; G10L 25/78; G10L 15/25; H04R 1/406; H04R 2430/01; G10K 2210/3044; H04R 2499/13; G10K 2210/1282; G10K 11/17823

(57) ABSTRACT

The invention includes a system for classifying sounds using a microphone, microphone array and/or a camera. The system can classify sounds and respective levels at different zones in an area such as a room, hall or vehicle passenger compartment. The system can use Active Noise Cancellation (ANC) to reduce unwanted sound and Automatic Loudness Control (ALC) to adjust levels of audio output such as music. The system can maintain a loudness ratio in each zone to create an optimal environment for music listening and/or conversation. The system can also be used to optimize the sound levels of broadcasted messages such as service announcements and advertisements.

### TECHNICAL FIELD

The present invention relates to an audio control system, and more specifically, to a system and method of monitoring and distinguishing sounds to automatically optimize those emitted from an audio output in a room, gathering area or passenger compartment of a vehicle.

### BACKGROUND

Noise pollution, often referred to as environmental noise, can be defined as noise that adversely impacts human activity. Sources of outdoor noise include sounds emitted by transport vehicles and machines such as industrial and domestic appliances. Because it is difficult to curb or cease many activities that cause noise, efforts are often directed at reducing levels of unwanted noise through passive noise control. For example, structural designs and the use of insulating materials can lower levels of background noise.

Music can also be used to contend with unwanted environmental or machine noise. The volume of music can be increased in attempt to overcome the noise. Automatic Loudness Control (ALC), also referred to as Automatic Volume Control (AVC), is a method of automatically adjusting music volume based on background noise. For example, the volume of a car stereo can be raised when background noises are detected that a listener desires to drown or block out. Because it is automated, the volume is adjusted without diverting the driver's attention away from operating the vehicle, which has obvious safety advantages. However, these systems have limitations. For example, human speech can be interpreted as background noise and the system will increase the stereo volume to block out the person speaking. Recent efforts have focused on improving ALC, particularly in automobiles.

U.S. patent application Ser. No. 10/703,604 describes a device for automatically controlling audio volume based on vehicle speed. The system uses speed-dependent volume control that increases the volume of a stereo as the speed of the vehicle increases. While it can be useful to automobile drivers and passengers, the system is based on an approximation of the background noise. It does not consider the actual noise level in the vehicle which can include engine noise, street conditions and sources of external noise. Moreover, the system does not account for the loudness of the audio signal (usually music). Music with soft tones will be less effective in overcoming background noise.

U.S. Pat. No. 9,508,344 describes a similar system for adjusting the volume of audio output in an automobile when human speech is detected. A microphone detects human speech based on the difference between the microphone output and audio head unit output. If human speech is detected, the system can lower the volume of the stereo to an appropriate level. However, detecting speech based on the difference between two outputs can be problematic. The residual signal due to the acoustic model of a vehicle (transfer function of speakers and microphones) can lead to instability of the system. The residual signal will increase the level that is considered noise and inevitably maximize the audio output.

These systems and others that use automatic music loudness control have limitations. For example, with high background noise, they can increase the volume of music beyond a comfortable or desirable level. Further, they do not account for volume at specific locations in an environment. An individual who is closer to a source of background noise area will experience higher levels because of their proximity.

Accordingly, there is a need for a system and method to more accurately and reliably improve audio conditions by reducing background noise and automatically adjusting the volume of audio output. The system should be capable of use in a large environment such as a meeting room, concert hall or transportation center as well as a small, enclosed environment such as the passenger compartment of an automobile.

### SUMMARY OF THE INVENTION

A system for automatic control of audio output in an area is described. The system can comprise a microphone, a camera, an audio output device and an automatic loudness control unit connected to the microphone, camera and audio output device. The microphone can detect sounds the area. The camera can detect human speech by monitoring facial and/or lip movements of individuals. The automatic loudness control unit adjusts audio output from the audio output device. Further, the automatic loudness control unit can respond to human speech that is detected in the area.

Embodiments also include a method of controlling audio output in an area comprising steps of (a) detecting sound levels with a microphone, (b) applying automatic loudness control to adjust audio output to maintain a loudness ratio, (d) detecting human speech by monitoring at least one of vocal sounds, facial movements and lip movements of an individual and (d) applying automatic loudness control to adjust audio output for human speech.

### INTRODUCTION

A first embodiment is a system and method of classifying sounds as background noise, audio output or human speech using a microphone, microphone array and/or a camera.

A second embodiment is a system and method of classifying sounds and respective levels in different zones of a gathering area or passenger compartment.

A third embodiment is a system and method of using an automatic loudness control unit to adjust the volume of audio output such as music in the presence of residual background noise.

A fourth embodiment is a method of detecting human speech by monitoring vocal sounds, facial movements and/or lip movements of one or more individuals in an area.

A fifth embodiment is a system and method of using Active Noise Cancellation (ANC) to reduce background noise in a zone of a gathering area or passenger compartment.

A sixth embodiment is a system and method of using ANC and/or ALC to optimize levels of audio output in different zones of a gathering area or passenger compartment.

A seventh embodiment is a system and method of using ANC and/or ALC to create an optimal sound environment for human conversation in a gathering area or passenger compartment.

An eighth embodiment is a system and method of estimating the age of a person by vocal sounds and/or facial characteristics/features of the person.

A ninth embodiment is a system and method of maintaining a loudness ratio based on individual preferences and/or an estimated age of an individual.

### BRIEF DESCRIPTION OF FIGURES

FIG. 1 depicts the process of sound classification, according to an embodiment.

FIG. 2A depicts the operation of the automatic audio control system, according to an embodiment.

FIG. 2B depicts the operation of the automatic audio control system with speech detection, according to an embodiment.

FIG. 2C depicts the steps of speech detection using audio feature extraction and visual feature extraction, according to an embodiment.

FIG. 3A depicts the operation of the automatic audio control system in the interior of a room, according to an embodiment.

FIG. 3B depicts the operation of the automatic audio control system in the interior of a room with a source of residual background noise, according to an embodiment.

FIG. 4 depicts the operation of the automatic audio control system in a large area such as an airport terminal, according to an embodiment.

FIG. 5A depicts the operation of the automatic audio control system in the interior of a vehicle such as an automobile, according to an embodiment.

FIG. 5B depicts the operation of the automatic audio control system in the interior of a vehicle with an external noise, according to an embodiment.

FIG. 5C depicts a method of detecting human speech and estimating the age of a person, according to an embodiment.

FIG. 5D depicts the operation of the automatic audio control system in the interior of a vehicle with human speech, according to an embodiment.

FIG. 6 depicts the operation of the automatic audio control system with a home surround sound system, according to an embodiment.

### DETAILED DESCRIPTION OF THE INVENTION

### Definitions

The term “Active Noise Cancellation,” “ANC,” “Active Noise Reduction,” or “ANR” refers to a method for reducing unwanted sound by the addition of a second sound designed to cancel the first sound. A noise-cancellation speaker emits a sound wave with the same amplitude but with inverted phase (also known as antiphase) to the original sound.

The term “audio output” refers to music or other audio content that is broadcast from a sound system such as a radio, stereo or computer. Speakers are a common output device used for amplifying and/or controlling the volume of audio output.

The term “automatic loudness control” or “ALC” refers to a method of automatically adjusting the volume of a radio or stereo to compensate for environmental or background noise.

The term “Controller Area Network,” “CAN” or “CANbus” refers to a vehicle bus standard designed to allow microcontrollers and devices to communicate with each other in applications without a host computer.

The term “gathering place” refers to any place where people are able to congregate such as, for example, city streets, town squares, parks, convention centers, transportation centers, cafes, stadiums, theaters, etc.

The term “intensity” of a sound refers to the amount of energy crossing a unit area in time or the power flowing through the unit area (e.g. watts per square meter).

The term “loudness” refers to the subjective perception of sound pressure. One hears sounds subjectively as quiet to loud, which depends on the scale of audio sound waves detected by the human ear.

The term “loudspeaker” refers to a device that changes electrical signals into sounds (e.g. music, announcements, etc.) loud enough to be heard at a distance.

The term “microphone” refers to a device that responds to sound pressure and transforms it into an electric signal with the same pattern of oscillation.

The term “microphone array” refers to any number of microphones operating in tandem. As used herein, a microphone array is used for monitoring environmental noise, distinguishing types/sources/locations of sounds from each other as well as detecting, monitoring and extracting voice input from ambient noise.

The term “pitch” refers to the highness or lowness of a sound. Sound waves with a low pitch have a low frequency. Likewise, sound waves with a high pitch have a high frequency.

The term “sound characteristics” refers to the pitch, duration, loudness, timbre and/or sonic texture of sound or noises. By measuring these characteristics and comparing them to know values/sounds, it is possible to identify or categorize a sound. For example, music typically has regular, rhythmic sound waves. Background noise can have more erratic sound waves with a less discernable pattern. Human speech can be identified by its waveform, duration, fundamental frequency and/or frequency domain features.

The term “sound pressure” or “acoustic pressure” refers to the local pressure deviation from the ambient (average or equilibrium) atmospheric pressure, caused by a sound wave. Sound pressure can be measured using a microphone.

The term “surround sound” or “surround sound stereo” refers to a technique for enriching the sound reproduction quality of an audio source with additional audio channels from speakers that surround a listener (“surround channels”). A typical standard surround system includes three front speakers LCR (left, center and right), two surround speakers LS and RS (left and right surround respectively) and a subwoofer for the Low Frequency Effects (LFE) channel.

The term “voice activity detection” or “speech detection” refers to one or more techniques used to detect the presence of human speech. Human speech in this context does not encompass spoken words or speech emitted from an audio output or speaker system.

Other technical terms used herein have their ordinary meaning in the art that they are used, as exemplified by a variety of technical dictionaries.

### Description of Preferred Embodiments

The particular values and configurations discussed in these non-limiting examples can be varied and are cited merely to illustrate at least one embodiment and are not intended to limit the scope thereof. For example, the invention can be used in large, open areas such as stadiums or sporting venues. It is also useful in small areas such as the interior space of an automobile or other passenger vehicle.

The invention recognizes the need for a system and method to optimize the levels of sound emitted from an audio output for one or more people in a gathering area or passenger compartment. The system can identify and classify the types and sources of sounds and account for the location(s) of listeners to accordingly vary the sound level of an audio output so that it can be more clearly discerned and/or enjoyed. In particular, the system can use ANC to cancel or reduce exterior or background sounds and ALC to automatically adjustment the volume of an audio output such as a radio/stereo or intercom system.

In a large area such as a train or airport terminal, the system can determine optimal sound levels for intercom announcements to be discernable and more clearly heard by listeners in different locations. In a smaller area such, as a home entertainment room or cinema screening room, the system can determine optimal sound levels of music/audio while accounting for undesirable background noises external or internal to the room. It can also be used in areas such as the passenger compartment of a motor vehicle to optimize levels of music/radio while accounting for conversation among passengers and undesirable background noise.

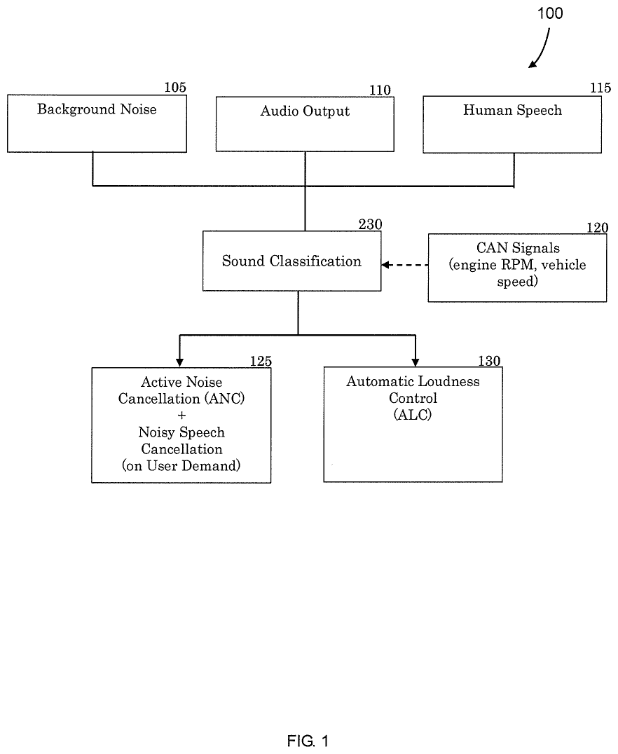

FIG. 1 depicts the types of sound and the process of sound classification 100 in a gathering area or a passenger compartment. The area or compartment can be outfitted with sensors to detect and measure sounds so that they can be distinguished from one another and classified. The sensors can include but are not limited to microphones, microphone arrays and cameras. A speaker system can include one or more speakers to broadcast audio output to the individuals in the area or compartment.

The system recognizes that there are different categories of sounds that an individual can experience within an environment. Categories of sound include background noise 105, audio output 110 (i.e. from one or more audio devices or systems) and human speech 115 (i.e. from an individual in the area). Sounds such as background noise can inhibit an individual's ability to clearly and discernably listen to a desirable audio content (e.g. speech or music).

### Background Noise

Background noise 105 includes extraneous or ambient sound that can be heard while listening to or monitoring other sounds (primary sounds). In a general sense, background noise is a form of noise pollution or interference of a primary sound desired to be heard by one or more individuals. Common noises that can be detected as background noise include road noise, wind noise, tire noise, engine noise, rain noise, bioacoustic noise from animals or birds and mechanical noise from devices such as refrigerators or air conditioning, power supplies or motors etc. For example, freeway noise is often a nuisance, especially when it can be heard from residential areas. In an automobile, background noise can include road and tire noise, wind noise, engine noise as well as environmental noises such as those attributable to rain. Further, in a room or large area, background noise can take the form of a generator, air conditioner unit, vacuum cleaner, fridge and/or other machine noise.

The system 100 can identify background noise by, for example, detecting its source and characteristics. For example, noise that is attributed to sources located outside of the room or gathering area (e.g. highway noise) can be identified as background noise. Sound that emanates from an external appliance such as an air conditioner unit or other appliance can also be identified as background noise. Sound wave characteristics can also be compared to distinguish background noise from other sounds such as music. Background noise will typically lack the identifiable sound characteristics of music and vocal sounds.

The system also accounts for residual background noise. In this context, residual background noise refers to undesired noise that is generally unpredictable and louder than the background noise. For example, an alarm or exterior noise from a construction project can be a residual background noise. Audio output can be increased to compensate for residual background noise.

### Audio Output

Audio output 110 refers to audio derived from an electronic device or system (e.g. radio, microphone, analog or digital recording) and emitted by a speaker system. Audio output can include vocal and instrumental musical sounds or spoken words from the radio, for example. Music is generally desired as an audio output, particularly when a listener has made efforts to transmit it. Accordingly, the system can identify music by, for example, its source (i.e. audio output) and characteristics. The signal characteristics and volume of output can be monitored as an identifying characteristic. Rhythmic sounds that are detected from a speaker source in the gathering area or passenger compartment can be identified as music through a sensor such as a microphone.

As music is usually desired, the system can take efforts to optimize the volume and sound quality of music through controlling the volume of undesirable noises. For example, ANC can be used to minimize background noise while ALC can be used to adjust the volume of the music.

### Human Speech

The system recognizes that it is generally desirable for a person to hear and understand human speech 115 when it is directed at him/her from another individual within the area or compartment. More specifically, the system can distinguish between speech emanating from an individual present in the area or compartment from speech emitted from an audio output device or system. Accordingly, the system can recognize a conversation between individuals physically present in the area or compartment and take efforts to improve the conditions for conversation, for example, by reducing the volume of the audio output. The system can apply “audio feature extraction” and/or “visual feature extraction” to identify human speech (discussed further below).

Referring to FIG. 1, the system can classify sounds 230 in the room/area as background noise 105, audio output 110 or human speech 115. The system can also use a CAN Network 120 to account for noises that are attributed to sources with known or predictable sound levels. For example, the system can account for engine revving and speed in the passenger compartment of an automobile, train, bus or aircraft. At higher speeds, passengers will experience greater engine and wind noise.

Thereafter, the system can optimize the sound environment for individual(s) in the gathering area or passenger compartment. Background noise can be reduced using Active Noise Cancellation (ANC) 125. Automatic Loudness Control (ALC) 130 can be used to adjust the audio output volume to an optimum level. ALC can raise the volume of music to compensate for residual background noise or lower the volume of music to create a better environment for conversation when a person begins speaking.

If human speech is detected, the system can use ANC and simultaneously reduce the volume of the audio output to create a better setting for conversation. When the speech subsides, the system can continue to use ANC to block out background noise and return the audio output volume to an optimum level.

In another embodiment, the system includes Noisy Speech Cancellation 125. ANC can be directed toward a person who is speaking within a particular zone (e.g. to reduce the volume of someone yelling). For example, the driver of a vehicle can activate the system to use ANC to mask or lower the sound of a passenger who is speaking toward him/her.

Residual background noise can also be present. For example, a residual background noise can be an alarm or siren from an emergency vehicle. While ALC can be applied to residual background noise, it is not targeted using ANC. Such noises can be necessary to alert others, particularly a driver. For safety, ANC is not applied to residual background noise. Accordingly, residual background can be defined as noise that remains present after ANC is applied.

In another embodiment, the system monitors and classifies the sounds and their respective volumes in distinct zones of the gathering area or passenger compartment. As will be appreciated, sound and noise pressure levels within an area or compartment will vary based on the locations of the sources of sounds and the extent that the sounds fade. For example, the system can recognize one or more distinct zones in a gathering area or passenger compartment, whereby in a standard four-seater automobile this can include four distinct zones comprised of the front left and right and rear left and right zones. Thereafter, the system can detect, monitor and classify the sounds in each zone and adjust the volume of the audio output accordingly in a personalized manner to the individual located within that zone.

The system is well suited for use in the passenger compartment of a motor vehicle or aircraft, in which case, ANC 125 and/or ALC 130 can be used in an audio head unit for each passenger. The system can also be used in large gathering places such as stadiums, convention centers, airports or concert halls.

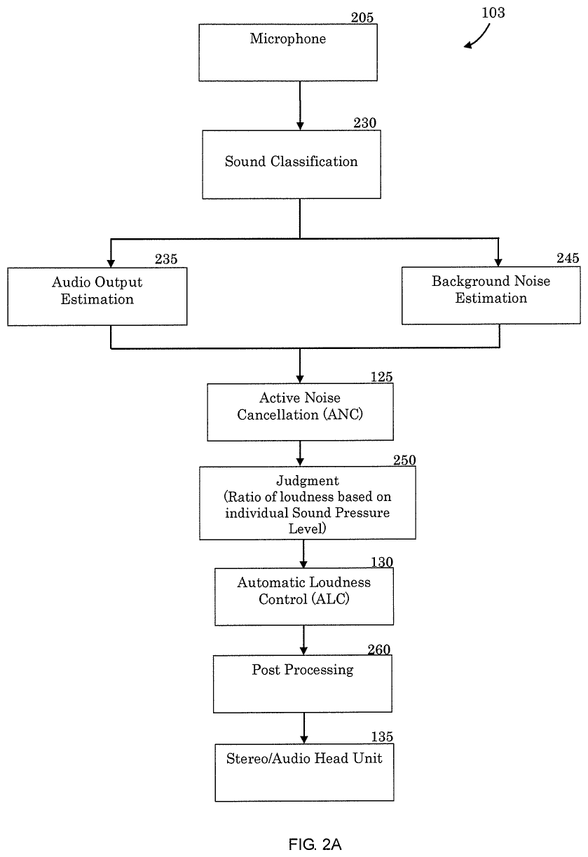

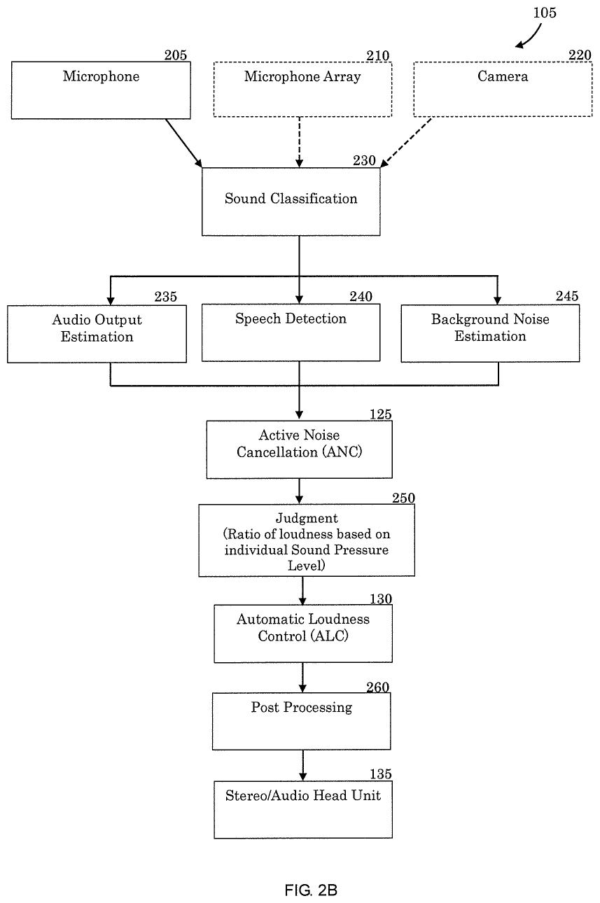

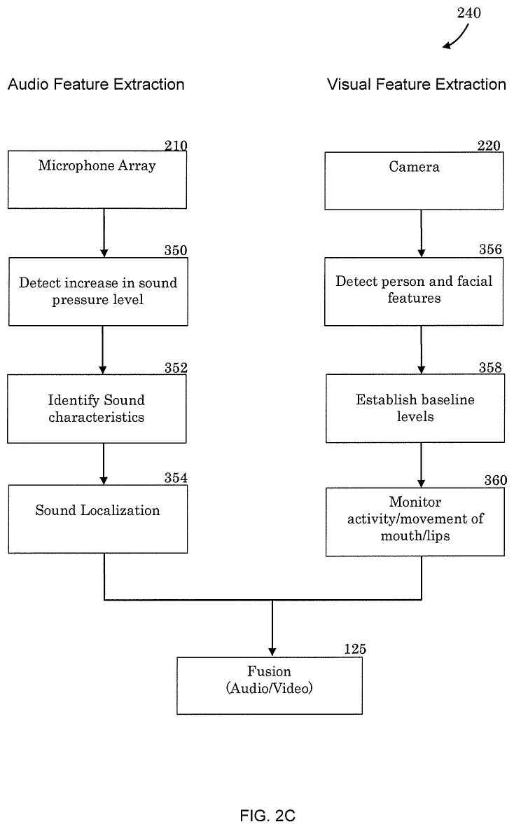

FIG. 2A depicts the operation of a system for automatic audio control 103 in a gathering area or passenger compartment. The system can monitor sound from a microphone 205. The microphone 205 can monitor background noise and audio output, whereby more than one microphone can be present depending on the size of the area and zones to monitor sound pressure levels. In the next step, the system can classify sounds 230.

The system can classify or categorize the sounds using audio output estimation 235 and background noise estimation 245. Audio output can be estimated by considering electronic signals (i.e. output voltage) and the resultant volume of audio output. Background noise can be identified as sound that is emitted from a source outside of the gathering area or passenger compartment. Further, background noise will typically not have the characteristics of audio output or human speech. In an embodiment where the system is applied to the interior compartment of a vehicle, background noise estimation can utilize vehicle data such as vehicle speed, engine revolutions (rpm), rain sensors and vibration sensors. Background noise can be reduced using Active Noise Cancellation (ANC) 125.

The system can judge the sound 250 which includes gauging the ratio of loudness of individual sounds. For example, the system can calculate the ratio of sound from audio output to background noise (i.e. the loudness ratio). Thereafter, the system can maintain this ratio by adjusting the volume of audio output using ALC 130. In the presence of residual background noise (e.g. an external sound and/or increase in background noise), the system can increase audio output to maintain the same loudness ratio. This step can be implemented in individual zones within a gathering area or passenger compartment.

ALC 130 can be used to adjust the volume of audio output such as music transmitted from loudspeakers. Specifically, ALC can adjust audio output to maintain the ratio of loudness of individual sounds. In the presence of residual background noise, audio output can be raised proportionally. The volume of audio output can be adjusted for each zone in the gathering area or passenger compartment.

A post-processing step 260 can be included to improve audio output. For example, the system can perform acoustic analyses based on the environment, user setting and type of output music. It can ensure that changes in audio output are gradual (i.e. smooth transitions) to improve the user experience. It can also determine parameters such as the maximum volume. In a passenger compartment, an audio head unit 135 can be used to optimize the audio environment for each passenger.

FIG. 2B depicts the operation of a system for automatic audio control 105 with the added component of speech detection. Through audio feature extraction, the system can monitor sound from a microphone 205 and/or a microphone array 210. The microphone array 210 can identify the sources of sound and can recognize human speech based on, for example, source location (i.e. determining whether the sound is derived from an individual) as well as sound wave characteristics. The microphone array 210 can also be used in conjunction with one or more cameras 220 to detect human speech. Through visual feature extraction, a camera 220 can identify facial movements and gestures that are indicative of human speech.

In the next step, the system can classify the sounds 230. It can categorize the sounds using audio output estimation 235, speech detection 240 and background noise estimation 245. Undesirable sounds such as background noise can be reduced using ANC 125. ANC can be used in each zone of the passenger compartment wherein a sound (i.e. antiphase) is emitted to cancel the dominant background noise.

The system can judge the sound 250 which includes gauging the ratio of loudness based on individual sounds. This step can account different zones in the gathering area or passenger compartment. Using the microphone 205 and/or microphone array 210, the system can locate the sources of sounds. For example, a sound can originate from the left side of a gathering place, in which case, individuals on the left side will experience a higher volume of the sound (i.e. a higher sound pressure level) because of their closer proximity to the source.

Thereafter, the system can optimize the sound environment for individual(s) in the gathering area or a passenger compartment. ALC 130 can simultaneously be used to adjust the volume of audio output. The volume can be adjusted based on the sounds and locations (e.g. zones) in the gathering area or passenger compartment. A post-processing step 260 can be included to improve audio output.

Each of the audio output speaker(s), microphone(s) and camera(s) can be connected to an automatic loudness control unit (not shown). The automatic loudness control unit can include a processor to receive and store data from each of the sensors and cameras. The automatic loudness control unit can also control and monitor one or more noise-cancellation speakers as well as audio output.

As discussed, the gathering place or passenger compartment can be divided into zones. ANC and/or ALC are applied individually in each zone, depending on the volume of sounds detected by the system. If the system identifies an exterior sound originating from the left side of a gathering place, it can apply a higher degree of ALC (i.e. a higher volume) to zones on the left side. For example, each passenger in a vehicle compartment can have a separate audio head unit 135, each with a microphone and one or more speakers. The system can control the volume of audio output from each audio head unit 135 with ALC while simultaneously applying ANC 125 to cancel/reduce background noise.

### Speech Detection

FIG. 2C depicts the steps of speech detection 240 in more detail. The system can use two approaches to identify human speech. A first approach utilizes a microphone array 210 and is referred to as “audio feature extraction.” A second approach utilizes one or more cameras 220 and is referred to as “visual feature extraction.” Data compiled from the two approaches can be fused 125 for more sensitive and accurate speech detection.

Through audio feature extraction, a microphone array 210 detects increases in sound pressure levels 350 that are not attributed to audio output or background noise. The microphone array can identify sound wave characteristics 352. For example, human speech can be identified by its waveform, duration, fundamental frequency and/or frequency domain features. The step of sound localization 354 identifies the source location. By determining the source of the sound, the system can determine whether the sound is derived from a person.

Through visual feature extraction, the system uses one or more cameras 220 to identify movements associated with speech such as lip/mouth movement and/or body/facial gestures of one or more individuals. For example, a camera in the passenger compartment of a vehicle can recognize individual people present and detect facial features of each person 356. Baseline levels of lip and mouth movement can be established 358 (i.e. the positions of one's lip and mouth when they are not speaking). The camera can continue to monitor activity of the lip and mouth of each person for movement attributable to speech 360. For example, many head movements and facial gestures (e.g. opening and closing of the mouth and lip) can be indicative of human speech.

Alternatively, the system can utilize different techniques. For example, the system can use color change technique to detect the presence of human speech of each person for movement attributable to speech 360. In the color change technique, the system identifies lips of the humans to be of same color. In cases if the system detects presence of any other color in between the two lip of the same color, the system identifies presence of human speech. For example, if the system detects lips separation for the person where any other color is identified to be present between the two lips of the human, the system judges that the human speech is occurring.

Further, in an example implementation of the present subject matter, the system can also utilize the variability in any of the above techniques to detect presence of human speech. For example, if the system detects change in color between two lips, frequently, for example more than 2 times, within a predetermined time period, for example 1 second (sec), the system detects presence of human speech.

Further, in an example implementation of the present subject matter, the system can monitor the thickness of the lip region to detect presence of human speech. If the system detects that the overall thickness of lips of any human is changing within a certain time, the system judges that the human speech is occurring.

Alternatively, both approaches can be used simultaneously for greater sensitivity and reliability whereby the audio data obtained from the microphone array is cross-referenced with the visual data obtained by the camera. A fusion step 125 can compile the audio and video data for speech detection.

Similarly, either or both approaches can be used when an individual initiates or receives a call on a mobile/cellular phone. The system can also incorporate modern smart phone technology (not shown). For example, a smart phone can send a signal to the system upon accepting or initiating a call. The system can thereafter take actions to improve audio conditions for the phone call conversation.

### Zonal Automatic Loudness Control

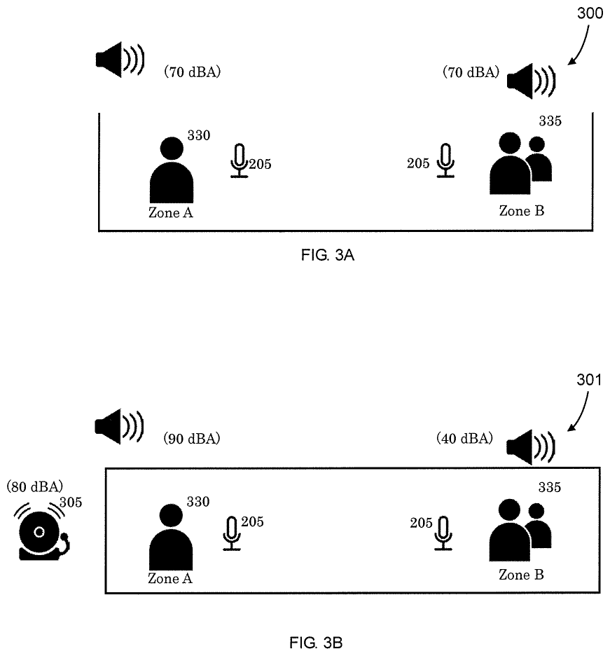

FIG. 3A depicts some embodiments of an automatic audio control system 300. Speakers broadcast music and/or announcements throughout a gathering place such as a conference room. The system can monitor sound from one or more microphones 205 and/or microphone arrays. Here, sound pressure levels are detected by a microphone 205 in each zone. The system can classify or categorize the sounds using audio output estimation and background noise estimation.

The system can use ALC to maintain an optimal or preferred loudness ratio (ratio of audio output to background noise). For example, in the absence of residual background noise, music or messages are broadcast at approximately 70 decibels (dBA) in both zones. The system monitors sound levels inside the room so that levels of audio output (e.g. broadcasted music or messages) to an individual in a first zone 330 (“zone A”) are at an equal or a comparable loudness ratio to those in a second zone 335 (“zone B”).

FIG. 3B depicts an automatic audio control system 301 with an external source of noise (i.e. residual background noise). In this example, a fire alarm 305 is detected by a microphone 205 in each zone. The sound can be identified as a high volume noise originating from outside the room. It can also be identified by characteristics such as its intensity and frequency. This external noise affects the individual in a zone A 330 who hears a ringing alarm at 80 dBA. Individuals in a zone B 335 are less affected because of their distance from the source. The sound is approximately 40 dBA at zone B.

Under these circumstances, an announcement broadcast into the room may not be discerned by individuals in zone A because of the alarm noise. The system can use ALC to ensure that an announcement (or other broadcasted audio) reaches all individuals in the room at an appropriate volume. ALC is applied at appropriate levels for each zone, that is, in proportion to the intensity of the ringing sound. The loudness ratio (ratio of audio output to background) noise can be determined

The volume of music and/or messages broadcasted to the individual in the zone A 330 can be increased to 90 dBA to compensate for the external noise 305. The system increases the volume of audio output in zone A to maintain the same loudness ratio. In this example, it is not necessary to increase the volume broadcasted to the individuals in the zone B because the noise from the alarm fades sufficiently over the distance between zones.

In detecting and adjusting the audio output, each zone can contain at least one audio output speaker and at least one sensor including the microphone, microphone array or camera. In another embodiment, each zone can comprise at least one audio output speaker and at least one microphone or microphone array. In yet another embodiment, each zone can comprise at least one audio output speaker, at least one microphone and at least one microphone array. In yet another embodiment, each zone can comprise at least one audio output speaker, at least one microphone, at least one microphone array and at least one camera.

### Operating Environment

The methods described herein, including the processes of data collection, sound classification, judgement and post processing, can be executed on a computer system, generally comprised of a central processing unit (CPU) that is operatively connected to a memory device, data input and output circuitry (I/O) and computer data network communication circuitry. Computer code executed by the CPU can take data received by the data communication circuitry and store it in the memory device. In addition, the CPU can take data from the I/O circuitry and store it in the memory device. Further, the CPU can take data from a memory device and output it through the I/O circuitry or the data communication circuitry. The data stored in memory may be further recalled from the memory device, further processed or modified by the CPU in the manner described herein and restored in the same memory device or a different memory device operatively connected to the CPU including by means of the data network circuitry. The memory device can be any kind of data storage circuit or magnetic storage or optical device, including a hard disk, optical disk or solid state memory. The I/O devices can include a display screen, loudspeakers, microphone and a movable mouse that indicate to the computer the relative location of a cursor position on the display and one or more buttons that can be actuated to indicate a command.

Data from the sensors (i.e. microphone and/or microphone array) and camera can be stored and analyzed in the computer or central processing unit (CPU) (i.e. automatic loudness control unit). Individual sounds can be characterized according to three categories: background noise, audio output and human speech. By considering the three categories, the system can take efforts to optimize the sound levels of individual zones through audio output in the gathering area or passenger compartment.

It should be noted that the flow diagrams are used herein to demonstrate various aspects of the invention, and should not be construed to limit the present invention to any particular logic flow or logic implementation. The described logic may be partitioned into different logic blocks (e.g., programs, modules, functions, or subroutines) without changing the overall results or otherwise departing from the true scope of the invention. Oftentimes, logic elements may be added, modified, omitted, performed in a different order, or implemented using different logic constructs (e.g., logic gates, looping primitives, conditional logic, and other logic constructs) without changing the overall results or otherwise departing from the true scope of the invention.

### Working Examples

### Use of the System in a Transit Center

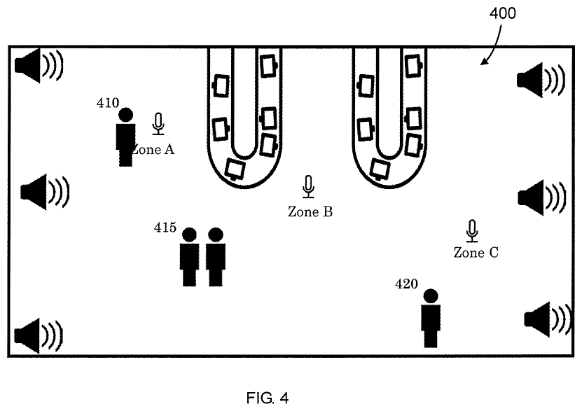

FIG. 4 depicts the operation of an automatic audio control system 400 in a gathering area such as an airport, bus station, train station or other transit center. The system can monitor sound from one or more microphones and/or microphone arrays to determine noise levels in different zones of the transit center. Sounds can include human noise, airplane noise, machine noise, etc.

Noise levels experienced by an individual in a first zone (“zone A”) 410 can be different from levels experienced by individuals in a second zone (“zone B”) 415 and/or an individual in a third zone (“zone C”) 420. In this example, the individual in zone A 410 is subject to noise from a baggage carousel. Noise emitted from the carousel can be identified based on its use (i.e. when switched one) as well as sounds associated with regular/prior use. The individual in zone C 420 is not subject to significant noise from the baggage carousel because of his/her distance away from it. By monitoring the noise level in each zone, the system can separately adjust the volume of audio output such as announcements for each zone.

An announcement is broadcast over speakers to all individuals in the transit center. The system can increase the volume of the announcement using speakers directed toward the individual in the zone A 410. A lower volume can be used for speakers directed toward the individual in zone C 420. By maintaining the same (or similar) loudness ratio, all passengers will have a similar listening experience regardless of levels of background or other noises. The same principle can be used for music that is broadcast through the transit center. The system can increase the volume of music directed toward the individual in the zone A 410 to account for noise originating from the baggage carousel.

### Use of the System in an Automobile

In an automobile, background noise can include road and tire noise, wind noise, engine noise as well as noise from rain. Background noise can be masked by increasing the volume of audio output such as music (i.e. by using ALC). However, it will be undesirable to increase the volume of music to such high levels that it is uncomfortable for passengers. Further, passengers may wish to converse, in which case, the level of audio output should be lowered.

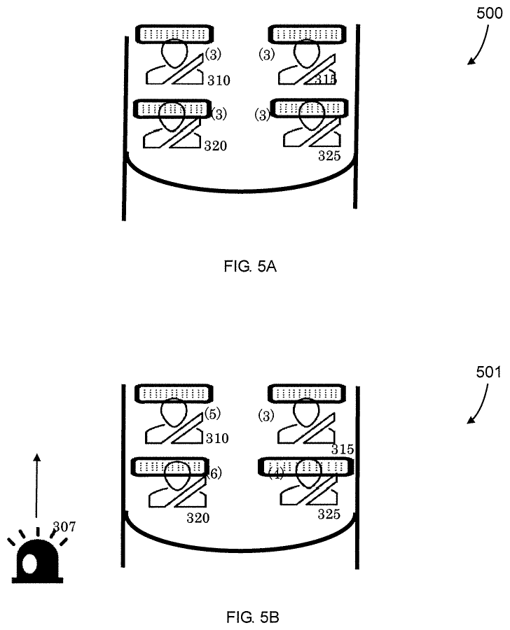

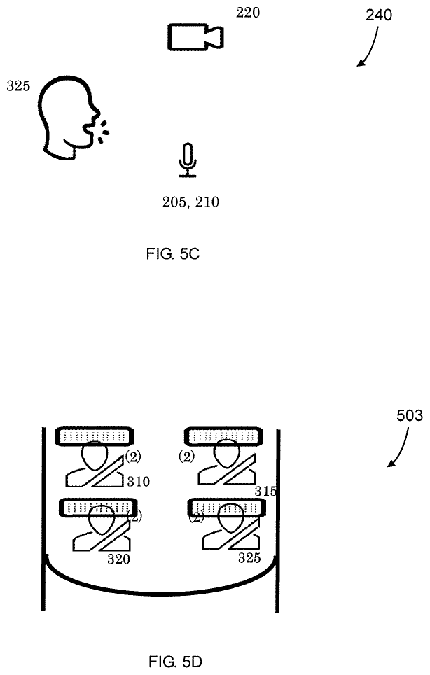

FIG. 5A depicts the use of an automatic audio control system 500 in the passenger compartment of an automobile. In this example, each passenger (310, 315, 320 and 325) has a head rest microphone. One or more speakers are directed to each passenger. Each passenger can choose a desired volume of music (i.e. preference for loudness in each zone). Here, each passenger sets the volume of music to a level of “three.” Based on a passenger's volume preference, the system (i.e. automatic loudness control unit) can maintain an optimal loudness ratio in their zone.

The system recognizes that each passenger is in a distinct zone and can experience different types of sounds. Types (i.e. categories) of sound include background noise, music and human speech. Moreover, each passenger can hear sounds at different intensities. A microphone and microphone array can monitor noise experienced by each passenger in their respective zone. The system can also include a CAN Network (or similar) to account for noises that are attributed to the automobile operation such as engine revving and speed.

The automatic loudness control unit can control loudness and noise cancellation automatically in each zone. It can continuously apply Active Noise Cancellation (ANC) in each zone to diminish the background noise experienced by each passenger. Under normal driving conditions, the dominant background noise is often engine noise. Accordingly, ANC can cancel/reduce the engine noise in each zone. This helps create a quiet environment for the passengers and/or a better environment for music or conversation. ALC can be used in the presence of residual background noise.

FIG. 5B depicts the operation of an automatic audio control system 501 in an automobile with an external source of noise 307. In this example, the passengers (310, 315, 320 and 325) experience an external noise (i.e. a residual background noise) 307 from a siren on a passing vehicle.

The system recognizes that sounds experienced by one passenger can be different from those experienced by other passengers. Each passenger sits in a separate zone. The noise from the siren can be different in each of the zones. Passengers closer to the source 307 will be more affected by the siren noise because of their proximity. The siren will initially affect the individual 320 in a first zone to the greatest extent.

The system can identify the external noise 307 by its source location and/or sound wave characteristic. The system can apply ALC at appropriate levels to maintain the optimal loudness ratio for each passenger. The volume of music (i.e. audio output) to the individual in a first zone 320 will be louder to compensate for the external noise 307. For example, the music volume directed to this passenger 320 is adjusted to six. The volume directed to the other front passenger 325 is adjusted to four. The passengers in the back seat close to the source 310 experiences a level of five. The other rear passenger 315 is less affected by the external sound and does not require a higher music volume. As the sound from the siren dissipates, the system can return the volume of music to three for each passenger.

The system can include settings to account for personal preferences of each passenger. For example, each passenger can indicate a preferred level of audio output. Thereafter, the system can use ALC to adjust the output volume to maintain a constant ratio of sound from audio output to background noise (i.e. loudness ratio). A passenger may have a preference for louder music. Because of the loud music (i.e. audio output), the ALC will be applied to a lesser degree than to a passenger with a preference for softer music.

In another embodiment, human speech can be detected by its source and characteristics as depicted in FIG. 5C. Speech detection 240 via a microphone and/or microphone array (205, 210) can identify the source and/or the soundwave characteristics of a passenger who speaks (i.e. audio feature extraction). Alternatively, one or more cameras 220 can identify movements associated with speech such as lip/mouth movement and body/facial gestures (i.e. visual feature extraction). When human speech is detected from a passenger, the system can create an environment for conversation. The system can continue to use ANC to reduce background noise while simultaneously using ALC to lower the stereo sound.

In another embodiment, data from the microphone, microphone array (205, 210) and/or one or more cameras 220 can be analyzed to estimate the age of a person. When human speech is detected, the sound characteristics can be analyzed to estimate his/her age. For example, the tone of one's voice can provide an indication of one's age. Facial features and characteristics from the camera can also be used in the estimation. Computer applications (i.e. apps) that estimate one's age based on photo characteristics are known in the art. Thereafter, the estimated age can be used in determining optimum sound levels for the person in their zone. For example, higher sound levels may be preferred in a zone with a person who has an estimated age of over 60 years old. Likewise, an older passenger may have less sensitive hearing and require a quieter environment to hear human speech. In contrast, a teenager may have more sensitive hearing and prefer lower sound levels.

FIG. 5D depicts the operation of an automatic audio control system 503 in an automobile when speech/conversation is detected. For example, the driver 325 can initiate a conversation with the other passengers. The system can recognize this from the driver's facial movements and gestures as well as sounds identified from his/her location as human speech. ANC can be continuously applied to reduce the engine noise and improve the environment for conversation. The system can reduce the music volume to two at each zone. When the system no longer detects human speech, it can return the music volume at each zone to three.

In another embodiment, the system can apply ANC or other sound suppressing methods to reduce loudness of noisy speech. A passenger can activate the system toward a person who is speaking within a particular zone. For example, the driver 325 may desire to reduce the volume/loudness of speech from the other front seat passenger 320. By activating noisy speech cancellation, the system can apply ANC or other sound suppressing methods to the vocal sounds emitted from the passenger 320.

The system can be similarly used in a cabin of a train, aircraft or bus. In a train, the system can recognize that interior noise pressure levels can vary depending on train speed. Levels can also be affected by different surfaces and when entering a bridge or tunnel. This type of information can be communicated through a CAN Network. As described above, ANC can be used in individual zones to reduce the background noise.

Similarly, the system can be used in the cabin of an aircraft and recognize that sound levels are different throughout the cabin. For example, background noise is generally higher near window seats, particularly those closest to the engines. In these areas, ANC can be directed at reducing engine noise. Likewise, in other areas, the background noise level can be attributed to an appliance (e.g. air conditioner, water pump, etc.). In these areas, ANC can be directed at reducing noise from appliances. Moreover, noise throughout the cabin will generally be higher during takeoff, landing and with higher engine power for ascending. The system can apply ANC at different zones or seats in the cabin to reduce the level of background noise (e.g. engine noise, air noise, wheel noise, etc.). Further, ALC can also be applied in each zone for passengers when music or messages are broadcasted.

Use of the System with a Home Entertainment System

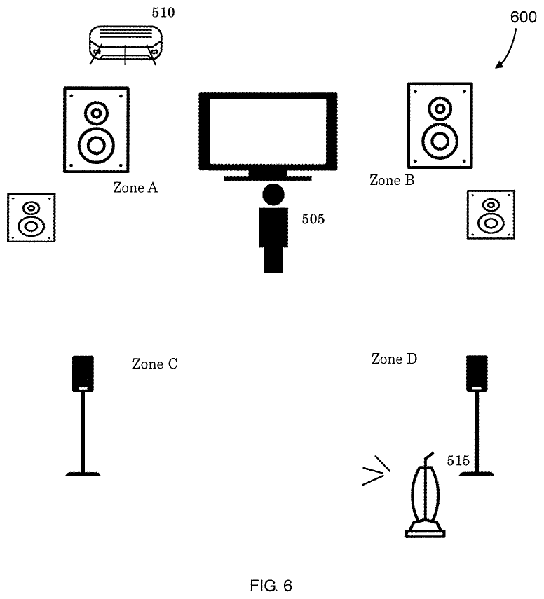

The system can also be used with a surround sound stereo system. FIG. 6 depicts an automatic audio control system 600 for use in conjunction with a home surround sound stereo system. The system can optimize the sound for a particular location (e.g. the center of a room or home theatre). In the alternative, the system can identify the location of listeners 505 by, for example, one or more cameras. It can then optimize the sound at the listeners' location.

In conventional surround sound systems, external sounds can be disruptive to a listener. In this example, an air conditioning unit 510 periodically emits noise of 50 dBA. A vacuum cleaner 515 is activated and emits a sound of 80 dBA. With a conventional system, the listener 505 will hear these external noises in addition to the surround sound audio.

The automatic audio control system 600 can identify background noise and adjust output of the surround sound system so that a listener is not disrupted. A microphone and/or microphone array can distinguish background noise from stereo audio (i.e. audio output). Sounds that are attributed to sources located outside of the surround sound system can be identified as background noise. Moreover, sounds that are not emitted from the surround sound system (e.g. non-music, non-theatrical, etc.) can be identified as background noise. Sound wave characteristics can also be compared to distinguish background noise from surround sound audio.

The system can define noise suppression zones based on the location of the listener and the speaker setup. Here, zone “A,” “B,” “C” and “D” are defined. Thereafter, the system can apply ANC as needed for each zone. In this example, the air conditioning unit 510 is a source of background noise in zone A. ANC can be applied in zone A to suppress the noise that is emitted from the air conditioner.

The system can also apply ALC at appropriate levels to individual speakers to account for residual background noise. In this example, the vacuum cleaner emits sound that is classified as residual background noise. ALC can increase the volume of speakers near zone D in response. With this approach, the system can maintain the quality of surround sound audio regardless of background noise.

In another embodiment, the system can identify human speech and improve sound conditions for conversation. For example, the listener 505 can initiate a conversation using a telephone. The system can recognize this from his/her facial movements and gestures as well as sounds identified from his/her location as human speech. The system can reduce the music volume to a lower or optimal level for the conversation. Simultaneously, ANC can be used to reduce background noise.

It will be appreciated that variations of the above disclosed and other features and functions, or alternatives thereof, may be combined into other systems or applications. Also, various unforeseen or unanticipated alternatives, modifications, variations or improvements therein may be subsequently made by those skilled in the art which are also intended to be encompassed by the following claims.

Although embodiments of the current disclosure have been described comprehensively, in considerable detail to cover the possible aspects, those skilled in the art would recognize that other versions of the disclosure are also possible.

1. A system for controlling of audio output in an area, said system comprising:
a first sensor to capture audio data corresponding to a human;
a second sensor to capture video data of the human, wherein the video data comprises a lip region of the human;
an audio output device; and
an automatic loudness control unit connected to the first sensor, the second sensor and the audio output device to:
analyze the video data to determine movement of lips of the human; and
adjust audio output from the audio output device based on detection of presence of human speech, and
wherein the automatic loudness control unit detects the presence of human speech based at least on analysis of the movement of lips of the human,
wherein the automatic loudness control unit detects whether any other color different from the lips is present at a region between the lips, and judges the presence of human speech occurred based on a frequency of detection of the any other color at the region between the lips within a predetermined period, and
wherein the automatic loudness control unit simultaneously reduces a volume of the audio output during the human speech being present.

2. The system of claim 1, wherein active noise cancellation is applied to the area to decrease background noise.

3. The system of claim 1, wherein the first sensor detects human speech by detecting vocal sounds emitted from one or more individuals in the area.

4. The system of claim 3, wherein the system estimates age of one or more individuals from the vocal sounds.

5. The system of claim 1, wherein the system estimates age of one or more individuals from facial features detected by the second sensor.

6. The system of claim 1, wherein the automatic loudness control unit maintains a loudness ratio based on at least one of individual preferences and an estimated age of an individual.

7. The system of claim 1, wherein the area is an interior space of a vehicle including one of an automobile, train, bus and aircraft.

8. The system of claim 7, wherein levels of background noise are determined by at least one of data on vehicle speed, motor/engine activity, vibrations and rain, which is relayed through a CAN network.

9. The system of claim 1, wherein the area is a home theatre or room with a system of surround sound speakers.

10. The system of claim 1, wherein the audio output comprises at least one of music, announcements and advertising material.

11. A method of controlling audio output in an area comprising steps of:
a. detecting sound levels with a first sensor;
b. detecting whether any other color different from lips of an individual is present at a region between the lips of the individual;
c. detecting human speech emitted from the individual based on a frequency of detection of the any other color at the region between the lips within a predetermined period;
d. adjusting audio output from the audio output device based on detection of presence of human speech; and
e. reducing a volume of the audio output simultaneously during the human speech being present.

12. The method of claim 11, including a step of applying active noise cancellation to a background noise.

13. The method of claim 11, including a step of estimating age of the individual based on at least one of vocal sounds emitted from the individual and facial features of the individual;
wherein the age is used to determine a loudness ratio.

14. The method of claim 11, wherein the area is an interior space in a vehicle including one of an automobile, train, bus and aircraft.

15. The method of claim 14, including a step of determining levels of background noise using data on at least one of vehicle speed, motor/engine activity, vibrations and rain, which is relayed through a CAN network.

16. The method of claim 11, wherein the area is a home theatre or room with a system of surround sound speakers.

17. The method of claim 11, wherein the audio output comprises at least one of music, announcements and advertising material.

18. A method of controlling audio output in an area comprising steps of:
a. detecting sound levels with a first sensor;
b. detecting human speech emitted from an individual by monitoring a frequency of color change at a region between lips of the individual within a predetermined time period;
c. adjusting audio output from the audio output device based on detection of presence of human speech; and
d. reducing a volume of the audio output simultaneously during the human speech being present.

19. A method of controlling audio output in an area comprising steps of:
a. detecting sound levels with a first sensor;
b. detecting human speech emitted from an individual by monitoring overall thickness of lips of the individual and a frequency of color change at a region between the lips of the individual within a predetermined time period;
c. adjusting audio output from the audio output device based on detection of presence of human speech; and
d. reducing a volume of the audio output simultaneously during the human speech being present.
